(19) United States
(12) Patent Application Publication
(10) Pub. No.: US 2013/0105774 A1
(43) Pub. Date: May 2, 2013

(54) OLED DISPLAYS FOR ACCURATE GRAY SCALES

(71) Applicant: UNIVERSAL DISPLAY CORPORATION, Ewing, NJ (US)

(72) Inventors: Vadim Adamovich, Yardley, PA (US); Lech Michalski, Pennington, NJ (US); Michael O'Connor, Ewing, NJ (US); Woo-Young So, Richboro, PA (US); Michael S. Weaver, Princeton, NJ (US); Michael Hack, Princeton, NJ (US); Julia J. Brown, Yardley, PA (US)

(73) Assignee: UNIVERSAL DISPLAY CORPORATION, Ewing, NJ (US)

(21) Appl. No.: 13/661,613

(22) Filed: Oct. 26, 2012

Related U.S. Application Data
(60) Provisional application No. 61/552,765, filed on Oct. 28, 2011.
(60) Provisional application No. 61/555,736, filed on Nov. 4, 2011.

(51) Int. Cl. H01L 27/32; H01L 51/56

(52) U.S. Cl. 257/40; 438/23; 257/E27.119; 257/E51.001

(57) ABSTRACT

A circuit for a pixel in a display device includes drive circuitry, an organic light emitting diode in electrical connection with the drive circuitry, and at least one resistive current path which is selected to be non-emissive in electrical connection with the drive circuitry and in parallel with the organic light emitting diode.

### CROSS-REFERENCE TO RELATED APPLICATIONS

This application claims priority to U.S. Provisional Patent Application Nos. 61/552,765, filed on Oct. 28, 2011, and 61/555,736, filed on Nov. 4, 2011, the entireties of which are herein incorporated by reference.

The claimed invention was made by, on behalf of, and/or in connection with one or more of the following parties to a joint university corporation research agreement: Regents of the University of Michigan, Princeton University, The University of Southern California, and the Universal Display Corporation. The agreement was in effect on and before the date the claimed invention was made, and the claimed invention was made as a result of activities undertaken within the scope of the agreement.

### FIELD

In a number of embodiments, devices, systems and methods hereof relate to organic light-emitting diode display devices and systems.

### BACKGROUND

The following information is provided to assist the reader in understanding technologies disclosed below and the environment in which such technologies may typically be used. The terms used herein are not intended to be limited to any particular narrow interpretation unless clearly stated otherwise in this document. References set forth herein may facilitate understanding the technologies or the background thereof The disclosure of all references cited herein are incorporated by reference.

Opto-electronic devices that make use of organic materials are becoming increasingly desirable for a number of reasons. Many of the materials used to make such devices are relatively inexpensive, so organic opto-electronic devices have the potential for cost advantages over inorganic devices. In addition, the inherent properties of organic materials, such as their flexibility, may make them well suited for particular applications such as fabrication on a flexible substrate. Examples of organic opto-electronic devices include organic light emitting devices (OLEDs), organic phototransistors, organic photovoltaic cells, and organic photodetectors. For OLEDs, the organic materials may have performance advantages over conventional materials. For example, the wavelength at which an organic emissive layer emits light may generally be readily tuned with appropriate dopants.

OLEDs make use of thin organic films that emit light when voltage is applied across the device. OLEDs are becoming an increasingly interesting technology for use in applications such as flat panel displays, illumination, and backlighting. Several OLED materials and configurations are described in U.S. Pat. Nos. 5,844,363, 6,303,238, and 5,707,745, which are incorporated herein by reference in their entirety.

One application for phosphorescent emissive molecules is a full color display. Industry standards for such a display call for pixels adapted to emit particular colors, referred to as “saturated” colors. In particular, these standards call for saturated red, green, and blue pixels. Color may be measured using International Commission on Illumination (CIE) coordinates, which are well known to the art.

One example of a green emissive molecule is tris(2-phenylpyridine) iridium, denoted Ir(ppy)₃, which has the following structure:

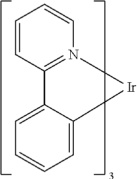

In this structure, we depict the dative bond from nitrogen to metal (here, Ir) as a straight line.

As used herein, the term “organic” includes polymeric materials as well as small molecule organic materials that may be used to fabricate organic opto-electronic devices. “Small molecule” refers to any organic material that is not a polymer, and “small molecules” may actually be quite large. Small molecules may include repeat units in some circumstances. For example, using a long chain alkyl group as a substituent does not remove a molecule from the “small molecule” class. Small molecules may also be incorporated into polymers, for example as a pendent group on a polymer backbone or as a part of the backbone. Small molecules may also serve as the core moiety of a dendrimer, which consists of a series of chemical shells built on the core moiety. The core moiety of a dendrimer may be a fluorescent or phosphorescent small molecule emitter. A dendrimer may be a “small molecule,” and it is believed that all dendrimers currently used in the field of OLEDs are small molecules.

As used herein, “top” means furthest away from the substrate, while “bottom” means closest to the substrate. Where a first layer is described as “disposed over” a second layer, the first layer is disposed further away from substrate. There may be other layers between the first and second layer, unless it is specified that the first layer is “in contact with” the second layer. For example, a cathode may be described as “disposed over” an anode, even though there are various organic layers in between.

As used herein, “solution processible” means capable of being dissolved, dispersed, or transported in and/or deposited from a liquid medium, either in solution or suspension form.

More details on OLEDs, and the definitions described above, can be found in U.S. Pat. No. 7,279,704, which is incorporated herein by reference in its entirety.

In active-matrix organic light-emitting diode (AMOLED) displays, an active matrix of OLED pixels is deposited or integrated onto a thin film transistor (TFT) array. Each of the driving TFTs of the array functions as a switch to control current flowing to the individual pixel associated the TFT. A shortcoming of AMOLED displays driven by, for example, polycrystalline silicon or poly-Si TFTs is that it is difficult to control low gray scales with high accuracy as a result of 1) the sub-threshold current having an exponential function, and 2) non-uniformity of the threshold voltage of the driving transistors. Higher resolution display devices require lower driving current for each subpixel. Since the sub-threshold current is an exponential function of the gate voltage controlled by display data, minor changes in threshold voltages of the transistors and/or non-uniformity of the transistor performance make significant changes in brightness in the low gray scales. In certain cases, the transistor's leakage current can supply a driving current to OLEDs, resulting in wrongly-addressed OLEDs (for example, wrong-gray-scale and partially-lit pixels).

### BRIEF SUMMARY

In summary, in one aspect, a circuit for a pixel in a display device includes drive circuitry, an organic light emitting diode in electrical connection with the drive circuitry, and at least one resistive current path which is selected to be non-emissive in electrical connection with the drive circuitry and in parallel with the organic light emitting diode. The resistive current path may, for example, include a resistor, a transistor, or a resistive layer of the display device. In a number of embodiments, a ratio of luminous efficacy at higher brightness to luminous efficacy at lower brightness is greater than 1. The ratio of luminous efficacy at 1000 cd/m² to luminous efficacy at 1 cd/m² may, for example, be greater than 1, greater than 5 or greater than 8.

The resistive current path may, for example, include a two-terminal transistor. In a number of embodiments, the resistive current path includes a section of an intrinsic or doped polycrystalline silicon layer, a section of an amorphous silicon layer, a section of a oxide semiconductor layer or a section of an organic semiconductor layer. The resistive current path may also include a conductive layer defining a boundary of the pixel.

In another aspect, a display includes a plurality of pixel circuits. At least one of the pixel circuits includes drive circuitry, an organic light-emitting diode in electrical connection with the drive circuitry, and at least one resistive current path which is selected to be non-emissive in electrical connection with the drive circuitry and in parallel with the organic light emitting diode.

In a further aspect, a method of fabricating a pixel circuit for an organic light-emitting diode display includes providing an organic light emitting diode in electrical connection with drive circuitry, and providing at least one resistive current path which is selected to be non-emissive in electrical connection with the drive circuitry and in parallel with the organic light emitting diode.

In still a further aspect, a method of controlling activation of a pixel circuit for an organic light-emitting diode of an organic light-emitting diode display includes providing at least one resistive current path which is selected to be non-emissive in parallel with the organic light emitting diode.

The pixel circuits hereof may, for example, be used in an AMOLED display, and are particularly useful in higher resolution display devices. Fabrication costs may, for example, be lowered by a higher fabrication yield. Introduction of additional non-emissive current paths to a pixel circuit of an OLED, which causes a greater fraction of the pixel current to become non-emissive at low luminance levels as compared to higher luminance levels, may, for example, prevent the pixel from being lit when an off-state is required or provide more accurate control in the lower brightness region, while maintaining approximately the same efficacy as the conventional pixel structure in the higher brightness region. The methods and structures hereof may, for example, provide reliable OLED display devices and significantly improve manufacturing yield.

The foregoing is a summary and thus may contain simplifications, generalizations, and omissions of detail; consequently, those skilled in the art will appreciate that the summary is illustrative only and is not intended to be in any way limiting.

For a better understanding of the embodiments, together with other and further features and advantages thereof, reference is made to the following description, taken in conjunction with the accompanying drawings. The scope of the claimed invention will be pointed out in the appended claims.

### BRIEF DESCRIPTION OF THE SEVERAL VIEWS OF THE DRAWINGS

FIG. 1 illustrates an embodiment of organic light emitting device.

FIG. 2 illustrates an embodiment of an inverted organic light emitting device that does not have a separate electron transport layer.

FIG. 3 illustrates an efficacy-vs-luminance plot for an OLED devices, of which area is 2 mm², including a parallel resistive path in the pixel circuitry thereof and for and OLED device without a parallel resistor in the pixel circuitry thereof.

FIG. 4 illustrates a generalized schematic circuit of an embodiment of circuitry for a pixel.

FIG. 5 illustrates a plot of current density (J) in mA/cm² as a function of OLED voltage in volts with and without a parallel resistor, wherein the legend shows the resistance of the parallel resistor.

FIG. 6 illustrates calculated resistance requirement (left axis) as a function of display resolution to achieve a RATIO of 10 with a 75 cd/A-efficacy OLED, wherein the right axis shows the required current to drive subpixels at 1 cd/m² with the same OLED.

FIG. 7 illustrates an embodiment of circuitry for a pixel to provide a high resistive current path parallel to the OLED.

FIG. 8A illustrates another embodiment of circuitry for a pixel to provide a resistive current path parallel to the OLED.

FIG. 8B illustrates a schematic cross-sectional view of a the pixel circuitry of FIG. 8A wherein a resistor is provided in parallel with the OLED using an intrinsic poly-Si layer, and wherein the OLED in not shown.

FIG. 9 illustrates a schematic cross-sectional view of an embodiment of a display system wherein a conductive grid defining the OLED pixels of the display system provides a resistive current path parallel to the OLED pixels.

### DETAILED DESCRIPTION

Generally, an OLED comprises at least one organic layer disposed between and electrically connected to an anode and a cathode. When a current is applied, the anode injects holes and the cathode injects electrons into the organic layer(s). The injected holes and electrons each migrate toward the oppositely charged electrode. When an electron and hole localize on the same molecule, an “exciton,” which is a localized electron-hole pair having an excited energy state, is formed. Light is emitted when the exciton relaxes via a photoemissive mechanism. In some cases, the exciton may be localized on an excimer or an exciplex. Non-radiative mechanisms, such as thermal relaxation, may also occur, but are generally considered undesirable.

Early OLEDs used emissive molecules that emitted light from their singlet states (“fluorescence”) as disclosed, for example, in U.S. Pat. No. 4,769,292, which is incorporated by reference in its entirety. Fluorescent emission generally occurs in a time frame of less than 10 nanoseconds.

More recently, OLEDs having emissive materials that emit light from triplet states (“phosphorescence”) have been demonstrated. Baldo et al., “Highly Efficient Phosphorescent Emission from Organic Electroluminescent Devices,” Nature, vol. 395, 151-154, 1998; (“Baldo-I”) and Baldo et al., “Very high-efficiency green organic light-emitting devices based on electrophosphorescence,” Appl. Phys. Lett., vol. 75, No. 3, 4-6 (1999) (“Baldo-II”), which are incorporated by reference in their entireties. Phosphorescence is described in more detail in U.S. Pat. No. 7,279,704 at cols. 5-6, which are incorporated by reference.

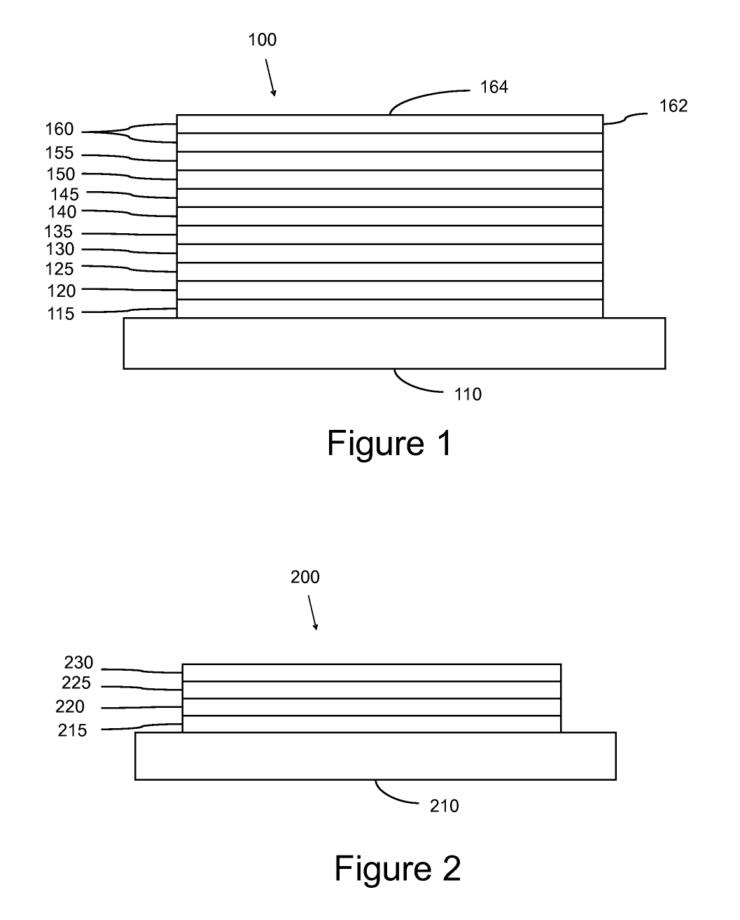

FIG. 1 illustrates an embodiment organic light emitting device 100. The figures are not necessarily drawn to scale. Device 100 may include a substrate 110, an anode 115, a hole injection layer 120, a hole transport layer 125, an electron blocking layer 130, an emissive layer 135, a hole blocking layer 140, an electron transport layer 145, an electron injection layer 150, a protective layer 155, a cathode 160, and a barrier layer 170. Cathode 160 is a compound cathode having a first conductive layer 162 and a second conductive layer 164. Device 100 may be fabricated by depositing the layers described, in order. The properties and functions of these various layers, as well as example materials, are described in more detail in U.S. Pat. No. 7,279,704 at cols. 6-10, which are incorporated by reference.

More examples for each of these layers are available. For example, a flexible and transparent substrate-anode combination is disclosed in U.S. Pat. No. 5,844,363, which is incorporated by reference in its entirety. An example of a p-doped hole transport layer is m-MTDATA doped with F₄-TCNQ at a molar ratio of 50:1, as disclosed in U.S. Patent Application Publication No. 2003/0230980, which is incorporated by reference in its entirety. Examples of emissive and host materials are disclosed in U.S. Pat. No. 6,303,238 to Thompson et al., which is incorporated by reference in its entirety. An example of an n-doped electron transport layer is BPhen doped with Li at a molar ratio of 1:1, as disclosed in U.S. Patent Application Publication No. 2003/0230980, which is incorporated by reference in its entirety. U.S. Pat. Nos. 5,703,436 and 5,707,745, which are incorporated by reference in their entireties, disclose examples of cathodes including compound cathodes having a thin layer of metal such as Mg:Ag with an overlying transparent, electrically-conductive, sputter-deposited ITO layer. The theory and use of blocking layers is described in more detail in U.S. Pat. No. 6,097,147 and U.S. Patent Application Publication No. 2003/0230980, which are incorporated by reference in their entireties. Examples of injection layers are provided in U.S. Patent Application Publication No. 2004/0174116, which is incorporated by reference in its entirety. A description of protective layers may be found in U.S. Patent Application Publication No. 2004/0174116, which is incorporated by reference in its entirety.

FIG. 2 illustrates an embodiment of inverted OLED 200. The device includes a substrate 210, a cathode 215, an emissive layer 220, a hole transport layer 225, and an anode 230. Device 200 may be fabricated by depositing the layers described, in order. Because the most common OLED configuration has a cathode disposed over the anode, and device 200 has cathode 215 disposed under anode 230, device 200 may be referred to as an “inverted” OLED. Materials similar to those described with respect to device 100 may be used in the corresponding layers of device 200. FIG. 2 provides an example of how some layers may be omitted from the structure of device 100.

The simple layered structure illustrated in FIGS. 1 and 2 is provided by way of non-limiting example, and it is understood that embodiments hereof may be used in connection with a wide variety of other structures. The specific materials and structures described are exemplary in nature, and other materials and structures may be used. Functional OLEDs may be achieved by combining the various layers described in different ways, or layers may be omitted entirely, based on design, performance, and cost factors. Other layers not specifically described may also be included. Materials other than those specifically described may be used. Although various layers may be described as including a single material, it is understood that combinations of materials, such as a mixture of host and dopant, or more generally a mixture, may be used. Also, the layers may have various sublayers. The names given to the various layers herein are not intended to be strictly limiting. For example, in device 200, hole transport layer 225 transports holes and injects holes into emissive layer 220, and may be described as a hole transport layer or a hole injection layer. In one embodiment, an OLED may be described as having an “organic layer” disposed between a cathode and an anode. This organic layer may comprise a single layer, or may further comprise multiple layers of different organic materials as described, for example, with respect to FIGS. 1 and 2.

Structures and materials not specifically described may also be used, such as OLEDs comprised of polymeric materials (PLEDs) such as disclosed in U.S. Pat. No. 5,247,190 to Friend et al., which is incorporated by reference in its entirety. By way of further example, OLEDs having a single organic layer may be used. OLEDs may be stacked, for example as described in U.S. Pat. No. 5,707,745 to Forrest et al, which is incorporated by reference in its entirety. The OLED structure may deviate from the simple layered structure illustrated in FIGS. 1 and 2. For example, the substrate may include an angled reflective surface to improve out-coupling, such as a mesa structure as described in U.S. Pat. No. 6,091,195 to Forrest et al., and/or a pit structure as described in U.S. Pat. No. 5,834,893 to Bulovic et al., which are incorporated by reference in their entireties.

Unless otherwise specified, any of the layers of the various embodiments may be deposited by any suitable method. For the organic layers, preferred methods include thermal evaporation, ink-jet, such as described in U.S. Pat. Nos. 6,013,982 and 6,087,196, which are incorporated by reference in their entireties, organic vapor phase deposition (OVPD), such as described in U.S. Pat. No. 6,337,102 to Forrest et al., which is incorporated by reference in its entirety, and deposition by organic vapor jet printing (OVJP), such as described in U.S. Pat. No. 7,431,968, which is incorporated by reference in its entirety. Other suitable deposition methods include spin coating and other solution based processes. Solution based processes are preferably carried out in nitrogen or an inert atmosphere. For the other layers, preferred methods include thermal evaporation. Preferred patterning methods include deposition through a mask, cold welding such as described in U.S. Pat. Nos. 6,294,398 and 6,468,819, which are incorporated by reference in their entireties, and patterning associated with some of the deposition methods such as ink-jet and OVJD. Other methods may also be used. The materials to be deposited may be modified to make them compatible with a particular deposition method. For example, substituents such as alkyl and aryl groups, branched or unbranched, and preferably containing at least 3 carbons, may be used in small molecules to enhance their ability to undergo solution processing. Substituents having 20 carbons or more may be used, and 3-20 carbons is a preferred range. Materials with asymmetric structures may have better solution processibility than those having symmetric structures, because asymmetric materials may have a lower tendency to recrystallize. Dendrimer substituents may be used to enhance the ability of small molecules to undergo solution processing.

OLED Devices may further optionally comprise a barrier layer. One purpose of the barrier layer is to protect the electrodes and organic layers from damaging exposure to harmful species in the environment including moisture, vapor and/or gases, etc. The barrier layer may be deposited over, under or next to a substrate, an electrode, or over any other parts of a device including an edge. The barrier layer may comprise a single layer, or multiple layers. The barrier layer may be formed by various known chemical vapor deposition techniques and may include compositions having a single phase as well as compositions having multiple phases. Any suitable material or combination of materials may be used for the barrier layer. The barrier layer may incorporate an inorganic or an organic compound or both. A barrier layer may, for example, comprise a mixture of a polymeric material and a non-polymeric material as described in U.S. Pat. No. 7,968,146, PCT Pat. Application Nos. PCT/US2007/023098 and PCT/US2009/042829, which are incorporated herein by reference in their entireties. To be considered a “mixture”, the aforesaid polymeric and non-polymeric materials comprising the barrier layer should be deposited under the same reaction conditions and/or at the same time. The weight ratio of polymeric to non-polymeric material may be in the range of 95:5 to 5:95. The polymeric material and the non-polymeric material may be created from the same precursor material. In one example, the mixture of a polymeric material and a non-polymeric material consists essentially of polymeric silicon and inorganic silicon.

Devices fabricated in accordance with embodiments hereof may be incorporated into a wide variety of consumer products, including flat panel displays, computer monitors, medical monitors, televisions, billboards, lights for interior or exterior illumination and/or signaling, heads up displays, fully transparent displays, flexible displays, laser printers, telephones, cell phones, personal digital assistants (PDAs), laptop computers, digital cameras, camcorders, viewfinders, micro-displays, vehicles, a large area wall, theater or stadium screen, or a sign. Various control mechanisms may be used to control devices fabricated in accordance with the methods hereof, including passive matrix and active matrix. Many of the devices are intended for use in a temperature range comfortable to humans, such as 18 degrees C. to 30 degrees C., and more preferably at room temperature (20-25 degrees C.).

The materials and structures described herein may have applications in devices other than OLEDs. For example, other optoelectronic devices such as organic solar cells and organic photodetectors may employ the materials and structures. More generally, organic devices, such as organic transistors, may employ the materials and structures.

The terms halo, halogen, alkyl, cycloalkyl, alkenyl, alkynyl, arylkyl, heterocyclic group, aryl, aromatic group, and heteroaryl are known to the art, and are defined in U.S. Pat. No. 7,279,704 at cols. 31-32, which are incorporated herein by reference.

It will be readily understood that the components of the embodiments, as generally described and illustrated in the figures herein, may be arranged and designed in a wide variety of different configurations in addition to the described example embodiments. Thus, the following more detailed description of the example embodiments, as represented in the figures, is not intended to limit the scope of the embodiments, as claimed, but is merely representative of example embodiments.

Reference throughout this specification to “one embodiment” or “an embodiment” (or the like) means that a particular feature, structure, or characteristic described in connection with the embodiment is included in at least one embodiment. Thus, the appearance of the phrases “in one embodiment” or “in an embodiment” or the like in various places throughout this specification are not necessarily all referring to the same embodiment.

Furthermore, the described features, structures, or characteristics may be combined in any suitable manner in one or more embodiments. In the following description, numerous specific details are provided to give a thorough understanding of embodiments. One skilled in the relevant art will recognize, however, that the various embodiments can be practiced without one or more of the specific details, or with other methods, components, materials, et cetera. In other instances, well known structures, materials, or operations are not shown or described in detail to avoid obfuscation.

As used herein and in the appended claims, the singular forms “a,” “an”, and “the” include plural references unless the context clearly dictates otherwise. Thus, for example, reference to “a resistor” or “a resistive path” includes a plurality of such resistors or resistive paths and equivalents thereof known to those skilled in the art, and so forth, and reference to “the resistor” or the “resistive path” is a reference to one or more such resistors or resistive paths and equivalents thereof known to those skilled in the art, and so forth.

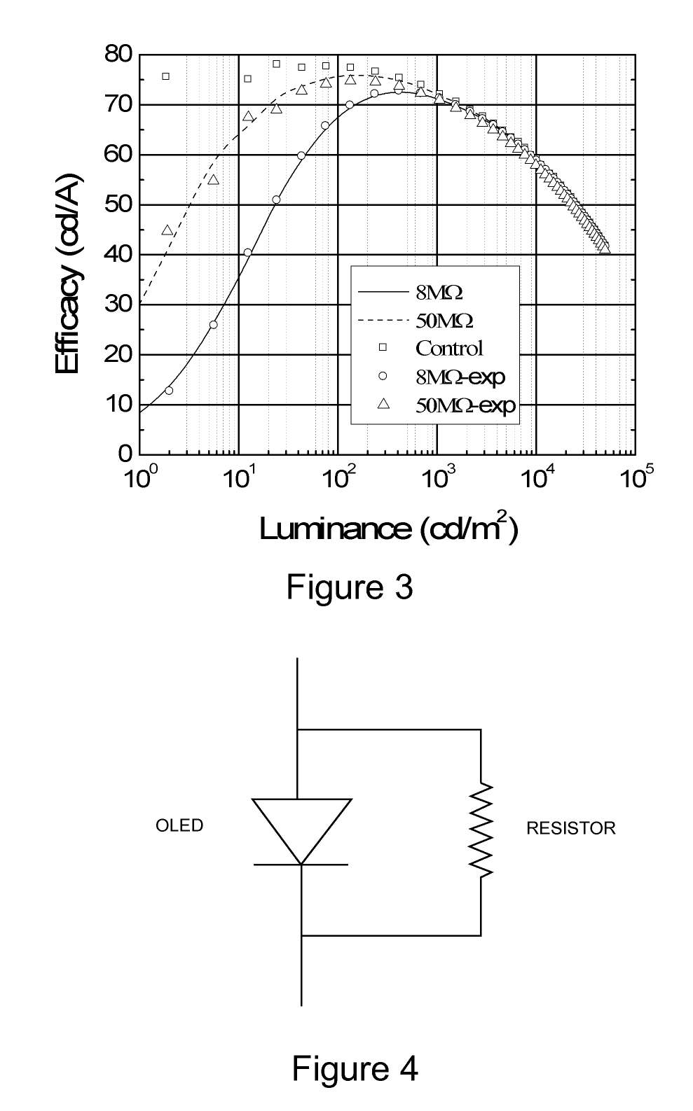

As performances of OLED devices such as phosphorescent OLED devices or PHOLED devices (including, for example, the current efficacy) are improved, the driving currents required are reduced. In particular, the driving current level at low brightness decreases significantly for high-resolution displays. For example, to drive a PHOLED of 100 cd/A at 1 cd/m² for a 300 dpi display, approximately 24 pA is needed. That order of current corresponds to a sub-threshold current of the driving transistors or the off-state current, depending on the dimensions or performances of the transistors. This low driving current causes technical difficulties in being accurately controlled in AMOLED displays, because 1) the sub-threshold current is an exponential function of the gate data voltage and 2) the threshold voltage of the driving transistors is not ideally uniform. Because of the former, highly-resolved data voltages are required to produce the correct linear gray scales. In reality, OLEDs may be lit much brighter than required for any specific video image. Similarly, the non-uniformity of the threshold voltage affects illumination of each pixel significantly. As set forth above, in certain circumstances, the highly efficient OLEDs can be lit partially in the off-state as a result of the comparable leakage current of the driving transistors. Therefore, lower luminous efficacy at lower brightness can be preferable to higher efficacy at lower brightness. Here, we define a ratio, which we refer to as the “RATIO” throughout the application, of efficacy at 1000 cd/m² to that at 1 cd/m² to quantify the characteristics. Most PHOLED devices have a RATIO close to unity as seen in FIG. 3 (refer to the square symbol, designating “Control”).

FIG. 3 illustrates an efficacy-vs-luminance plot for an OLED devices including a parallel resistive path in the pixel circuitry thereof and for an OLED device without a parallel resistor in the pixel circuitry thereof. The legend sets forth the resistance of the parallel resistor. The area of the tested PHOLED device was 2 mm² As illustrated in FIG. 3, with a resistor as a parallel non-emissive current path, the efficacy at lower luminance decreases while that at higher luminance remains virtually the same. A proper choice of the resistance can control the RATIO. For example, an 8 MΩ resistor can give the RATIO of 8.5. In this way, the introduction of an additional non-emissive current path parallel to the OLEDs can prevent the pixel from being lit partially or provide more accurate control in the lower brightness region while keeping virtually the same efficacy as the conventional pixel structure at higher brightness.

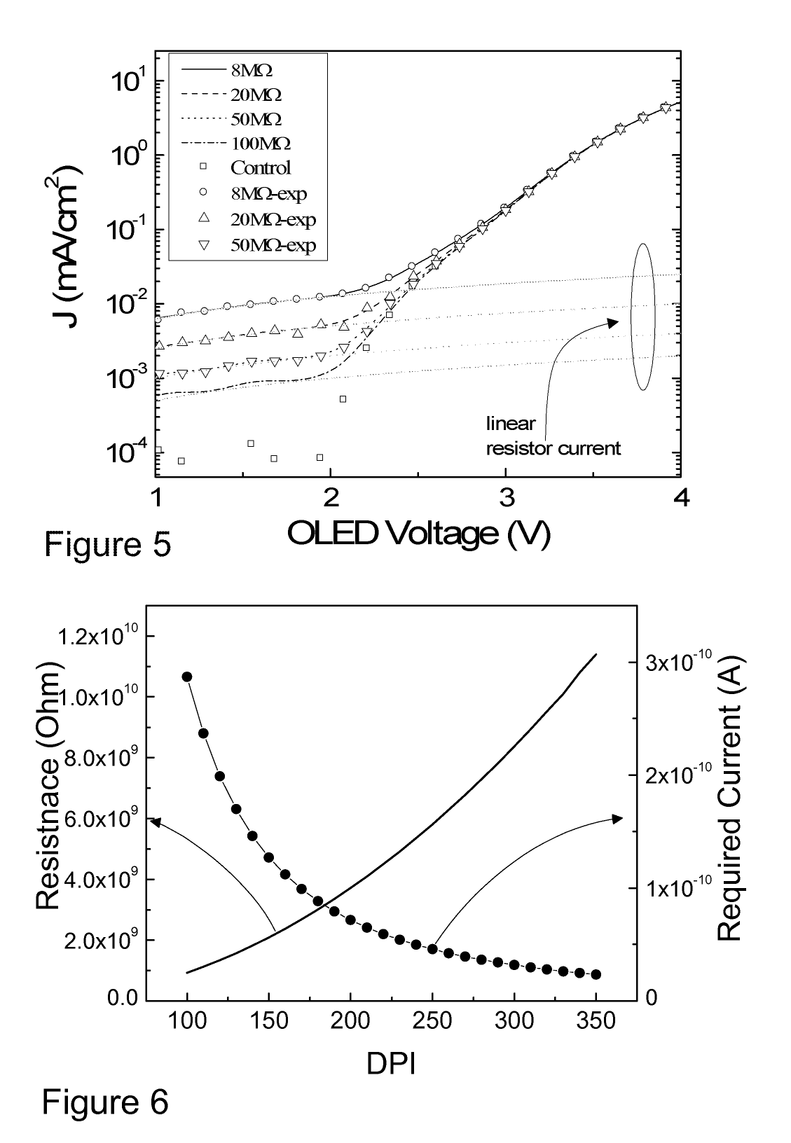

Thus, to increase the RATIO, in a number of embodiments hereof, a non-emissive current path was implemented parallel to the OLED at low brightness. OLEDs exhibit highly non-linear resistance, with OLED resistance at lower voltages being significantly greater than OLED resistance at higher voltages. FIG. 5 illustrates a plot of current density (J) in mA/cm² as a function of OLED voltage in volts with and without the presence of a parallel resistor (as described in FIG. 4). As seen in FIG. 5, at lower voltage, at which lower brightness is generated, the resistor current is far more dominant than the OLED current. As illustrated in FIG. 5, attaching a parallel resistor determines the current level below 2V of OLED voltage. At high brightness (higher voltages), however, the linear current through the resistor is negligible compared to the non-linear current through the OLED. In other words, the effective resistance of the non-emissive and resistive current path is less than the OLED resistance at lower voltage. However, at higher voltage, the effective resistance of the non-emissive and resistive current path is greater than the OLED resistance. Since the resistor current is non-emissive, the current efficacy at lower voltage or brightness is suppressed at a given current as desired. In FIG. 5, the legend shows the resistance of the parallel resistor. Symbol plots show experimental data, while line plots indicate numerical calculation results in FIG. 5. The area of the tested PHOLED device studied was 2 mm².

Estimates of the required resistance to drive subpixels in AMOLED displays can be made as a function of display resolution, Dots Per Inch (DPI). In a representative example, the resistance requirements based on an OLED with a current efficacy of 75 cd/A was calculated. The results are shown in FIG. 6. Once again, in higher resolution displays the required current to drive the subpixel at 1 cd/m² is reduced (plotted with the lined symbol). The solid line shows the parallel resistance necessary to obtain a RATIO of 10. The right axis in FIG. 6 shows the required current to drive subpixels at 1 cd/m² with the same OLED. Approximately 8.4 GΩ is needed for a 300 dpi-display. The calculations for current and resistance underlying the data set forth in FIG. 6 are set forth below.

$$I = \frac{L}{LE} \times \frac{{( 0.0254 / DPI )}^{2}}{3} \times ( RATIO - 1 )$$

wherein I is the required resistive current per subpixel in amps (A), L is Lumiance in nits, candela/m² or cd/m², LE is Luminous Efficacy in candela/amp or cd/A, and resolution/DPI is provided in dots per inch.

$$R = \frac{{V}_{OLED}}{\frac{L}{LE} \times \frac{{( 0.0254 / DPI )}^{2}}{3} \times ( RATIO - 1 )}$$

wherein R is resistance of the parallel resistor in Ohm and V_{OLED} is measured from an OLED J-V curve (see, for example, FIG. 5) such that J is L/LE x (RATIO-1), wherein J is current density.

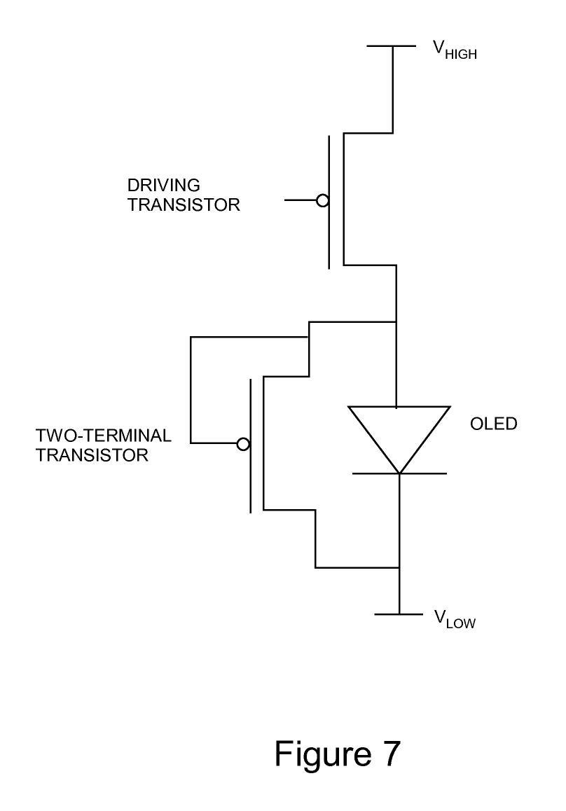

The high resistive current path described herein may, for example, be achieved in a number of manners without adding significant complications to fabrication. For example, the required resistance may be achieved using a two-terminal transistor in parallel with an OLED as depicted in FIG. 7. The transistor may, for example, be a conventional 3-terminal TFT with the gate directly connected to one of the source or drain contacts. The illustrated two-terminal transistor is realized by connecting electrically the gate to the source of a transistor. Because the gate and the source are connected in common, the transistor remains in the off-state all the time in a given bias configuration and provides a current path at the off-state leakage current level.

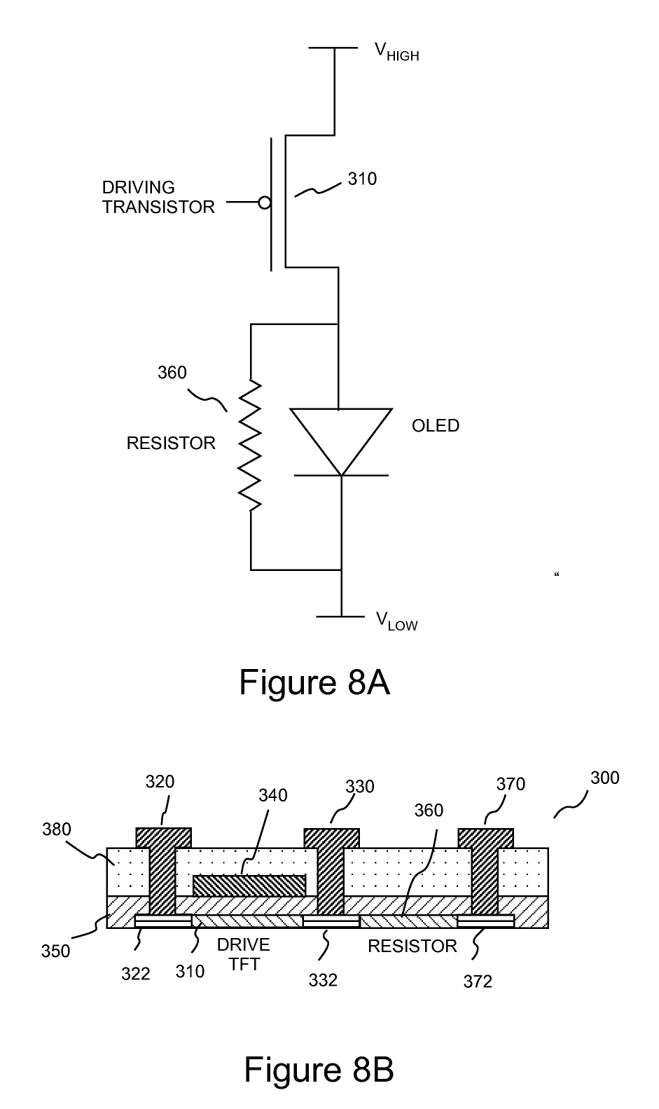

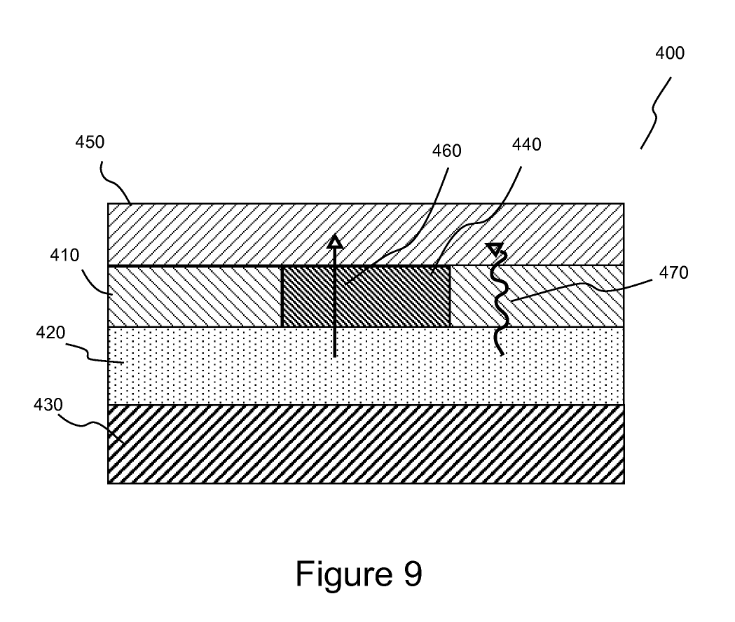

In other embodiments, an intrinsic or lightly doped poly-Si layer may be used to provide a resistive pathway in parallel with the OLED. Typically, the poly-Si layer has a resistivity of about 10⁴ Ωcm, depending on its material conditions. A typical thickness of 50 nm for a thin film transistor (TFT) provides a sheet resistance of 2 GΩ/sq (gigaohms per square). A desired resistance range may be attained by controlling the ratio of the width and length of the poly-Si film. An embodiment of pixel circuitry including the poly-Si layer as the resistor is illustrated in FIG. 8A. A schematic cross-sectional structure of the pixel circuitry of FIG. 8A is illustrated in FIG. 8B. In FIG. 8B, pixel circuitry 300 includes a driving TFT which includes a section 310 of poly-Si material disposed between a section 322 of highly-doped poly-Si in contact with a source 320 and a section 332 of highly-doped poly-Si in contact with a drain 330. A gate 340 is isolated from poly-Si channel 310 via a gate insulator 350. In a parallel resistive path portion of pixel circuitry 300, a section 360 of intrinsic or lightly doped poly-Si material is disposed between section 332 of highly-doped poly-Si material and another section of highly-doped poly-Si material 372 which contacts to the power line, V_{Low}, through intermetal 370 (for example, a metallic connector). In the illustrated embodiment, an interlayer 380 is positioned over or on top of gate 340 and gate insulator 350. Many other materials may be used a resistors. In general, whatever materials are used for the TFT active layer may be used to form a resistor. Such materials include, for example, amorphous silicon, oxide materials or organic materials. FIG. 9 illustrates another embodiment of a portion of a display system 400 hereof in which a resistive path is introduced parallel to an OLED pixel in a display. Similar to the embodiments described above, the parallel resistive path of FIG. 9 is introduced without adding significant complications to fabrication. In the embodiment of FIG. 9, a conductive grid 410 is formed over an anode 420 (which is positioned on top of a substrate 430) in a manner to define OLED pixels 440 (only one of which is illustrated in FIG. 9) in display system 400. The conductivity/resistance of conductive grid 410 is controlled to meet the required resistance range as discussed above to provide an additional/parallel conductive/resistive path from anode 420 to cathode 450. The positions of anode 420 and cathode 450 in FIG. 9 may be reversed. In FIG. 9, an emissive current path, through pixel 440, is represented by arrow 460, while a non-emissive, parallel resistive current path is represented by wavy line 470.

Conductive grid 410 may, for example, be prepared by adding fine conductive powder into a polyimide grid precursor. The precursor may, for example, be coated over substrate 430 and processed by photolithography to form a grid to define pixels 440. The conductive powder may, for example, be composed of fine metal particles (for example, Al, Cu, Ag, and/or Zn) or some other conductive materials (for example, TiN, or semiconductor materials). In a number of embodiments, the size of the particles is chosen to be significantly less than the thickness of conductive grid 410 to avoid increasing the film roughness and, thereby, maintaining a high device yield. The conductivity of the material and concentration of the particles in conductive grid 410 may be varied to “tune” the resistance of conductive grid 410 and to affect the RATIO.

This disclosure has been presented for purposes of illustration and description but is not intended to be exhaustive or limiting. Many modifications and variations will be apparent to those of ordinary skill in the art. The example embodiments were chosen and described in order to explain principles and practical application, and to enable others of ordinary skill in the art to understand the disclosure for various embodiments with various modifications as are suited to the particular use contemplated.

Thus, although illustrative example embodiments have been described herein with reference to the accompanying figures, it is to be understood that this description is not limiting and that various other changes and modifications may be affected therein by one skilled in the art without departing from the scope or spirit of the disclosure.

What is claimed is:

1. A circuit for a pixel in a display device, comprising:
drive circuitry;
an organic light emitting diode in electrical connection with the drive circuitry; and
at least one resistive current path which is selected to be non-emissive in electrical connection with the drive circuitry and in parallel with the organic light emitting diode.

2. The circuit of claim 1 wherein the resistive current path comprises a resistor, a transistor, or a resistive layer of the display device.

3. The circuit of claim 1 wherein a ratio of luminous efficacy at higher brightness to luminous efficacy at lower brightness is greater than 1.

4. The circuit of claim 1 wherein a ratio of luminous efficacy at 1000 cd/m² to luminous efficacy at 1 cd/m² is greater than 1.

5. The circuit of claim 1 wherein a ratio of luminous efficacy at 1000 cd/m² to luminous efficacy at 1 cd/m² is greater than 5.

6. The circuit of claim 1 wherein a ratio of luminous efficacy at 1000 cd/m² to luminous efficacy at 1 cd/m² is greater than 8.

7. The circuit of claim 2 wherein the resistive current path comprises a two-terminal transistor.

8. The circuit of claim 2 wherein the resistive current path comprises a layer of the display device.

9. The circuit of claim 2 wherein the resistive current path comprises a section of an intrinsic or lightly doped polycrystalline silicon layer, a section of an amorphous silicon layer, a section of an oxide semiconductor layer or a section of an organic semiconductor layer.

10. The circuit of claim 9 wherein the resistive current path comprises a conductive layer defining a boundary of the pixel.

11. A display comprising a plurality of pixel circuits, at least one of the pixel circuits, comprising:
drive circuitry;
an organic light-emitting diode in electrical connection with the drive circuitry; and
at least one resistive current path which is selected to be non-emissive in electrical connection with the drive circuitry and in parallel with the organic light emitting diode.

12. A method of fabricating a pixel circuit for an organic light-emitting diode display, comprising:
providing an organic light emitting diode in electrical connection with drive circuitry; and
providing at least one resistive current path which is selected to be non-emissive in electrical connection with the drive circuitry and in parallel with the organic light emitting diode.

13. The method of claim 12 wherein the resistive current path comprises a resistor, a transistor, a resistive layer of the display device.

14. The method of claim 12 wherein a ratio of luminous efficacy at higher brightness to luminous efficacy at lower brightness is greater than 1.

15. The method of claim 12 wherein a ratio of luminous efficacy at 1000 cd/m² to luminous efficacy at 1 cd/m² is greater than 1.

16. The circuit of claim 12 wherein a ratio of luminous efficacy at 1000 cd/m² to luminous efficacy at 1 cd/m² is greater than 5.

17. The method of claim 12 wherein a ratio of luminous efficacy at 1000 cd/m² to luminous efficacy at 1 cd/m² is greater than 8.

18. The method of claim 12 wherein the resistive current path comprises a two-terminal transistor.

19. The method of claim 12 wherein the resistive current path comprises a layer of the display device.

20. The method of claim 13 wherein the resistive current path comprises a section of an intrinsic or lightly doped polycrystalline silicon layer, a section of an amorphous silicon layer, a section of an oxide semiconductor layer or a section of an organic semiconductor layer.

21. The method of claim 20 wherein the resistive current path comprises a conductive layer defining a boundary of the pixel.

22. A method of controlling activation of a pixel circuit for an organic light-emitting diode of an organic light-emitting diode display, comprising:
providing at least one resistive current path which is selected to be non-emissive in parallel with the organic light emitting diode.
